(19) United States
(12) Patent Application Publication
(10) Pub. No.: US 2026/0247574 A1
(43) Pub. Date: Aug. 20, 2026

(54) HEAT-DISSIPATING DEVICE, ELECTRONIC DEVICE INCLUDING THE HEAT-DISSIPATING DEVICE, AND HEAT-DISSIPATING METHOD OF THE ELECTRONIC DEVICE

(71) Applicant: Samsung Display Co., Ltd., Yongin-si (KR)

(72) Inventor: MINKI KIM, Yongin-si (KR)

(21) Appl. No.: 19/462,706

(22) Filed: Jan. 28, 2026

(30) Foreign Application Priority Data
Feb. 18, 2025 (KR) 10-2025-0020682

(51) Int. Cl. H05K 7/20; G06F 1/20

(52) U.S. Cl. CPC H05K 7/20336; G06F 1/203; G06F 1/206; H05K 7/20381; H05K 7/2099; G06F 2200/201

(57) ABSTRACT

A heat-dissipating device, an electronic device including the heat-dissipating device, and a heat-dissipating method are provided. The heat-dissipating device includes a capillary in which a working fluid is to travel and a capillary-force controller. The capillary includes a first section configured to absorb heat generated by a heat source, a second section spaced from the first section and configured to dissipate the absorbed heat, and a third section connecting the first and second sections. The capillary-force controller is in the third section and is configured to increase or decrease capillary-force such that the working fluid that has absorbed the heat in the first section moves to the second section, and the working fluid that has released the heat in the second section moves back to the first section.

### CROSS-REFERENCE TO RELATED APPLICATION

The present application claims priority to and the benefit of Korean Patent Application No. 10-2025-0020682, filed on February 18, 2025, in the Korean Intellectual Property Office, the entire disclosure of which is incorporated herein by reference.

### BACKGROUND

### 1 . Field

Embodiments of the present disclosure relate to a heat-dissipating device, an electronic device including the heat-dissipating device, and a heat-dissipating method of the electronic device. For example, embodiments of the present disclosure pertain to a heat-dissipating device including a pulsating heat pipe ("PHP"), an electronic device including the heat-dissipating device, and a heat-dissipating method using the same.

### 2 . Description of the Related Art

High-resolution, high-luminance electronic devices use a higher input power level. However, a rise in input power may elevate the temperature of the electronic device.

Heat-conductive methods, carbon materials (e.g., natural graphite sheets, synthetic graphite, and/or the like), aluminum, copper, and/or the like may be used to regulate heat in the electronic device. In addition, for example, heat pipes, vacuum chambers, and/or the like may be used to regulate heat in the electronic device.

A heat pipe may include an internal wick structure. As the thickness of the heat pipe decreases, a vapor-flow path of the heat pipe narrows and thermal performance may degrade.

To address this, pulsating heat pipes ("PHP") have been developed. The PHP may transfer heat via oscillation of an operating liquid and vapor plugs inside a bundle of capillary channels, without a wick.

The above information disclosed in this Background section is intended to enhance understanding of the background of the disclosure and may contain information that does not constitute prior art.

### SUMMARY

Aspects of one or more embodiments of the present disclosure are directed toward a heat-dissipating device with enhanced operational stability.

Aspects of one or more embodiments of the present disclosure are directed toward an electronic device including the heat-dissipating device.

Aspects of one or more embodiments of the present disclosure are directed toward a heat-dissipating method of the electronic device.

Additional aspects will be set forth in part in the description which follows and, in part, will be apparent from the description, or may be learned by practice of the presented embodiments of the disclosure.

A heat-dissipating device according to one or more embodiments of the present disclosure includes: a capillary in which a working fluid is to travel, the capillary including: a first section configured to absorb heat generated by a heat source, a second section spaced and/or apart (e.g., spaced apart or separated) from the first section and configured to dissipate the absorbed heat, and a third section connecting the first section and the second section; and a capillary-force controller located in the third section and configured to increase or decrease capillary-force such that the working fluid absorbing the heat in the first section moves to the second section and the working fluid releasing the heat in the second section moves to the first section.

In one or more embodiments, the third section may include a 3-1 subsection to guide the working fluid from the first section to the second section and a 3-2 subsection to guide the working fluid from the second section to the first section, and the capillary-force controller may include a surface-treatment part having a surface energy greater in the 3-1 subsection than in the 3-2 subsection.

In one or more embodiments, the working fluid may alternately form a vapor phase and a liquid phase, and a contact angle defined by the liquid phase working fluid and the vapor phase working fluid at an inner surface of the surface-treatment part may increase along a flow direction in the 3-1 subsection and decrease along the flow direction in the 3-2 subsection.

In one or more embodiments, the third section may include a 3-1 subsection to guide the working fluid from the first section to the second section and a 3-2 subsection to guide the working fluid from the second section to the first section, and the capillary-force controller may include a diameter-varying part configured such that an inner diameter of the 3-1 subsection increases along a flow direction of the working fluid and an inner diameter of the 3-2 subsection decreases along the flow direction of the working fluid.

In one or more embodiments, the third section may include a 3-1 subsection to guide the working fluid from the first section to the second section and a 3-2 subsection to guide the working fluid from the second section to the first section, and the capillary-force controller may include a surface area modifier such that a surface area of an inner wall of the 3-1 subsection decreases along a flow direction of the working fluid and a surface area of an inner wall of the 3-2 subsection increases along the flow direction of the working fluid.

In one or more embodiments, the surface area modifier may include a protrusion protruding from an inner surface of the 3-2 subsection.

In one or more embodiments, the surface area modifier may include a mesh arranged inside the 3-2 subsection.

In one or more embodiments, the surface area modifier may include linear structures arranged inside the 3-2 subsection.

In one or more embodiments, the surface area modifier may include a porous material arranged inside the 3-2 subsection.

An electronic device according to one or more embodiments of the present disclosure includes: a display device; and a heat-dissipating device to cool the display device, the heat-dissipating device including: a capillary in which a working fluid is to travel, the capillary including: a first section configured to absorb heat generated by a heat source, a second section spaced and/or apart (e.g., spaced apart or separated) from the first section and configured to dissipate the absorbed heat, and a third section connecting the first section and the second section; and a capillary-force controller located in the third section and configured to increase or decrease capillary-force such that the working fluid absorbing the heat in the first section moves to the second section and the working fluid releasing the heat in the second section moves to the first section.

In one or more embodiments, the third section may include a 3-1 subsection to guide the working fluid from the first section to the second section and a 3-2 subsection to guide the working fluid from the second section to the first section, and the capillary-force controller may include a surface-treatment part having a surface energy greater in the 3-1 subsection than in the 3-2 subsection.

In one or more embodiments, the working fluid may alternately form a vapor phase and a liquid phase, and a contact angle defined by the liquid phase working fluid and the vapor phase working fluid at an inner surface of the surface-treatment part may increase along a flow direction in the 3-1 subsection and decrease along the flow direction in the 3-2 subsection.

In one or more embodiments, the third section may include a 3-1 subsection to guide the working fluid from the first section to the second section and a 3-2 subsection to guide the working fluid from the second section to the first section, and the capillary-force controller may include a diameter-varying part configured such that an inner diameter of the 3-1 subsection increases along a flow direction of the working fluid and an inner diameter of the 3-2 subsection decreases along the flow direction of the working fluid.

In one or more embodiments, the third section may include a 3-1 subsection to guide the working fluid from the first section to the second section and a 3-2 subsection to guide the working fluid from the second section to the first section, and the capillary-force controller may include a surface area modifier such that a surface area of an inner wall of the 3-1 subsection is smaller than a surface area of the inner wall of the 3-2 subsection or the surface area of the inner wall of the 3-1 subsection decreases along a flow direction of the working fluid and a surface area of an inner wall of the 3-2 subsection increases along the flow direction of the working fluid.

In one or more embodiments, the surface area modifier may include: at least one selected from among a group including (e.g., consisting of) a protrusion protruding from an inner surface of the 3-2 subsection or the 3-1 subsection, a mesh arranged inside the 3-2 subsection, linear structures arranged inside the 3-2 subsection, and a porous material arranged inside the 3-2 subsection.

In one or more embodiments, the electronic device of claim 10 may further include: a surface-energy-change section on a portion of an inner surface of a flow path, the surface-energy-change section including a first zone and a second zone that alternate with each other, the first zone having a first surface energy, and the second zone having a second surface energy different from the first surface energy.

In one or more embodiments, an inner surface of the first zone may be hydrophilic, and an inner surface of the second zone may be hydrophobic.

A heat-dissipating method of an electronic device according to one or more embodiments of the present disclosure includes: forming, on a portion of an inner surface of a flow path, a surface-energy-change section including a first zone and a second zone that alternate with each other, the first zone having a first surface energy, and the second zone having a second surface energy lower than the first surface energy; charging the flow path with a working fluid; and dissipating heat from a heat source while the working fluid travels through the flow path.

In one or more embodiments, wherein the working fluid alternately forms a vapor phase and a liquid phase, and wherein the step (e.g., act or task) of dissipating the heat from the heat source while the working fluid travels through the flow path includes: interrupting the flow of the liquid phase working fluid at an interface between the first zone and the second zone; forming a liquid column by surface tension at the interface; and reducing a size of the vapor phase working fluid by the liquid column.

In one or more embodiments, the heat source may include at least one selected form a group consisting: a display device including multiple pixels and an electronic device including the display device and an outer case accommodating the display device.

The heat-dissipating device according to one or more embodiments of the present disclosure may include the capillary-force controller in the third section. Thus, according to aspects or one or more embodiments of the present disclosure, the heat-dissipating device may improve heat dissipation performance without changing the flow path, working fluid, and dry-out heat capacity (“max Q”). Because the heat-dissipating device according to one or more embodiments of the disclosure may include the capillary-force controller, the capillary-force controller may lower (quickly lower) the maximum temperature of the display device with an initial start-up even with low heat input.

According to aspects or one or more embodiments of the present disclosure, the heat-dissipating device may control a direction of heat transfer by controlling a degree of cooling at a specific location. For example, the working fluid evaporated in the evaporation section may flow to the condensation section, and the working fluid condensed in the condensation section may flow to the evaporation section, thereby rapidly lowering the maximum temperature of the display device. In one or more embodiments, it is also possible to concentrate cooling on a specific location.

In one or more embodiments of the present disclosure, the heat-dissipating device may be designed in one or more suitable ways depending on the location of the heat source, heat capacity, and/or the like. For example, if (e.g., when) heat generation is greatest in a central portion of a monitor, the heat-dissipating device may be positioned to disperse heat from the central portion of the monitor to an edge portion.

In one or more embodiments, the heat-dissipating device according to one or more embodiments of the present disclosure may be customized in consideration of a usage environment. For example, it may be applied to one or more suitable fields such as batteries in addition to display devices.

In one or more embodiments, the heat-dissipating device according to one or more embodiments of the disclosure may be applicable to a vertically driven monitor. In the case of heat-dissipating devices, a length of a vibrating heat pipe may be short, so it cannot be applied to a large-area monitor, and if (e.g., when) installed vertically, there the working fluid may accumulate at the bottom due to gravity, resulting in a lack of circulation and ineffective heat dissipation. The heat-dissipating device according to one or more embodiments of the disclosure may artificially induce the circulation flow by increasing/decreasing the capillary-force.

According to aspects or one or more embodiments of the present disclosure, the heat-dissipating device according to one or more embodiments of the disclosure may prevent or reduce dry-out by including the energy-change section.

### BRIEF DESCRIPTION OF THE DRAWINGS

The accompanying drawings are included to provide a further understanding of the present disclosure and are incorporated in and constitute a part of this specification. The drawings illustrate example embodiments of the present disclosure and, together with the description, serve to explain principles of the present disclosure. In the drawings:

FIG. 1 is a block diagram illustrating an electronic device according to one or more embodiments of the present disclosure.

FIG. 2 shows schematic perspective diagrams of electronic devices according to embodiments of the present disclosure.

FIG. 3 is an exploded perspective view illustrating an electronic device according to one or more embodiments of the present disclosure.

FIG. 4 is a plan view illustrating a display device of FIG. 3, according to one or more embodiments of the present disclosure.

FIG. 5 is a block diagram illustrating the display device of FIG. 3, according to one or more embodiments of the present disclosure.

FIG. 6 is a plan view of a heat-dissipating device, according to one or more embodiments of the disclosure.

FIG. 7 schematically shows a flow path of the heat-dissipating device of FIG. 6, according to one or more embodiments of the disclosure.

FIG. 8 is a cross-sectional view taken along a length of a capillary of the heat-dissipating device at region A of FIG. 6, according to one or more embodiments of the disclosure.

FIG. 9 is a cross-sectional view taken along a length of a portion of a capillary of a heat-dissipating device, according to one or more embodiments of the disclosure.

FIG. 10 is a cross-sectional view taken along a length of the capillary at region A of FIG. 6, according to one or more embodiments of the disclosure.

FIG. 11 is a cross-sectional view taken along the line II-II’ of FIG. 10, according to one or more embodiments of the present disclosure.

FIGS. 12 – 14 are each a cross-sectional view taken along a length of a portion of a capillary of a heat-dissipating device, according to embodiments of the present disclosure.

FIG. 15 is a perspective view of a portion of the surface-energy-change section of FIG. 6, according to embodiments of the present disclosure.

FIG. 16 is a cross-sectional view taken along the line IV-IV’ of FIG. 15, according to embodiments of the present disclosure.

FIG. 17 is a cross-sectional view taken along the line IV-IV’ of FIG. 15, according to embodiments of the present disclosure.

FIG. 18 is a schematic view illustrating a groove formed on the inner surface of the flow path of FIG. 15, according to embodiments of the present disclosure.

FIGS. 19 – 23 are cross-sectional views of the capillary of the heat-dissipating device of FIG. 6 illustrating a heat-dissipation method of an electronic device using the heat-dissipating device, according to one or more embodiments of the disclosure.

FIGS. 24 and 25 are views illustrating the heat source associated with the heat-dissipating device of FIG. 6.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, duplicative descriptions thereof may not be provided. In the drawings, the relative sizes (e.g., including lengths, widths and thicknesses) of elements, layers, and regions may be exaggerated for clarity.

Spatially relative terms, such as “on,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element, such as an area, layer, film, region or portion, is referred to as being “on” or “connected to” another element, it can be directly on or connected to the other element, or one or more intervening elements may be present. In contrast, when an element or layer is referred to as being “directly on,” “directly connected to”, or “immediately adjacent to” another element or layer, there are no intervening elements or layers present. In addition, it will also be understood that when an element is referred to as being “between” two elements, it can be the only element between the two elements, or one or more intervening elements may also be present.

As used herein, the singular forms “a,” “an” and “the” are intended to include the plural forms as well, unless the context clearly indicates otherwise. It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions "at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

The display device according to one or more embodiments may be applied to a variety of electronic devices. The electronic device according to one or more embodiments includes the aforementioned display device and may include a module or apparatus having other additional functions in addition to the display device.

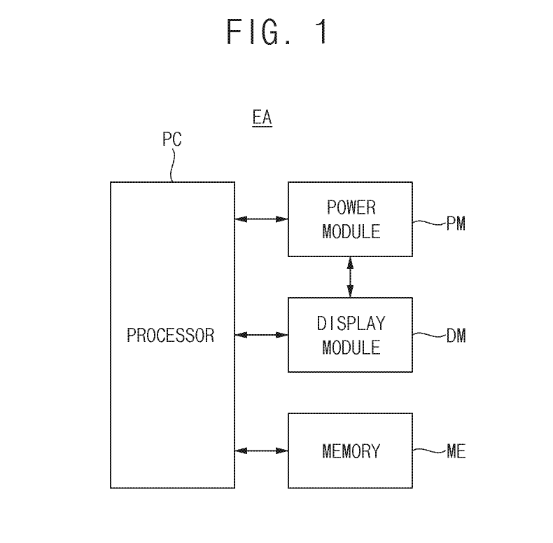

FIG. 1 is a block diagram illustrating an electronic device according to one or more embodiments of the present disclosure.

Referring to FIG. 1, an electronic device EA according to one or more embodiments may include a display module DM, a processor PC, a memory ME, and a power module PM.

The processor PC may include a central processing unit (“CPU”), an application processor (“AP”), a graphic processing unit (“GPU”), a communication processor (“CP”), an image signal processor (“ISP”), and/or a controller.

Data information for operation of the processor PC or the display module DM may be stored in the memory ME. When the processor PC executes an application stored in the memory ME, an image data signal and/or an input control signal may be transmitted to the display module DM, and the display module DM may process received signals and output image information through a display screen.

The power module PM may include a power supply module such as a power adapter and/or a battery device, and a power conversion module that converts power supplied by the power supply module to generate power for operation of the electronic device EA.

At least one of the components of the electronic device EA described above may be included in the display device according to one or more embodiments of the present disclosure. In addition, some of individual modules functionally included in one module may be included in the display device, and others may be provided separately from the display device. For example, the display device may include the display module DM, and the processor PC, the memory ME, and the power module PM may be provided in the form of another device in the electronic device EA other than the display device. In one or more embodiments, the display device may operate based on the image data signal and the input control signal.

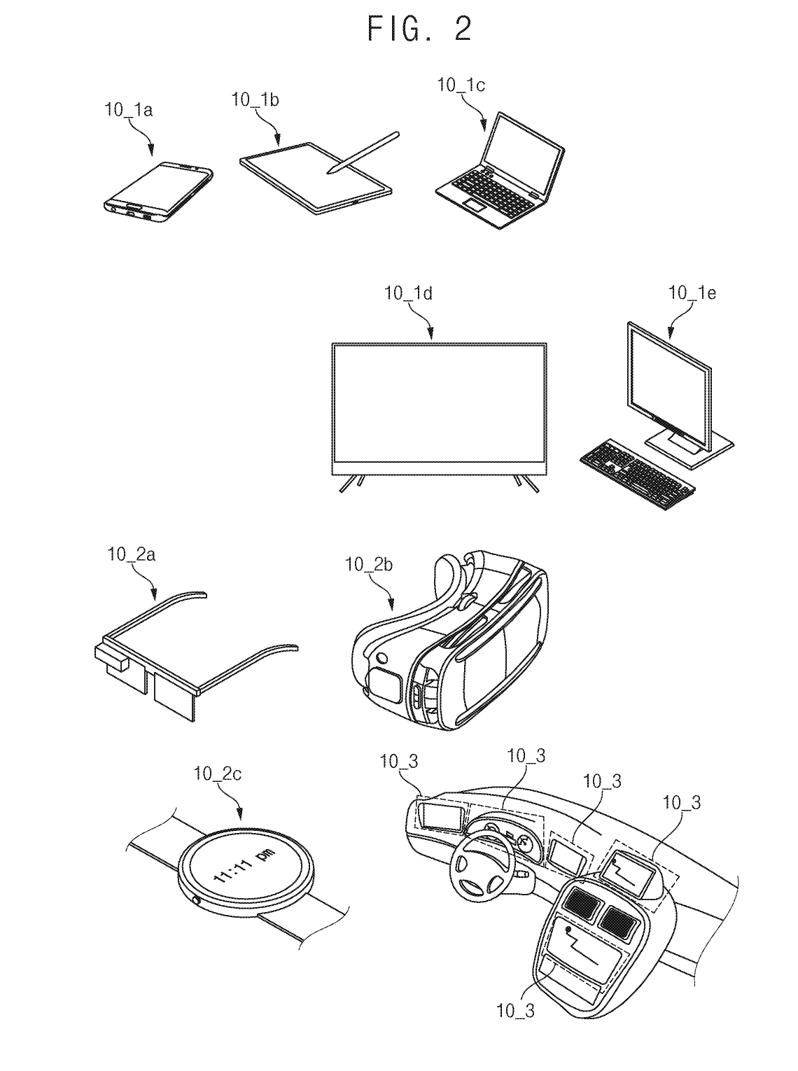

FIG. 2 shows schematic perspective diagrams of electronic devices according to one or more suitable embodiments of the present disclosure.

Referring to FIG. 2, one or more suitable electronic devices 10 to which display devices according to one or more embodiments are applied may include not only electronic devices for image display such as a smartphone 10_1a, a tablet PC 10_1b, a laptop 10_1c, a TV 10_1d, a desk monitor 10_1e, and/or the like, but wearable electronic devices including display modules such as smart glasses 10_2a, a head mounted display 10_2b, a smart watch 10_2c, and/or the like, vehicle electronic devices 10_3 including display modules such as on a vehicle's instrument panel, a center fascia, a center information display (“CID”) located on a dashboard, a room mirror display, and/or the like.

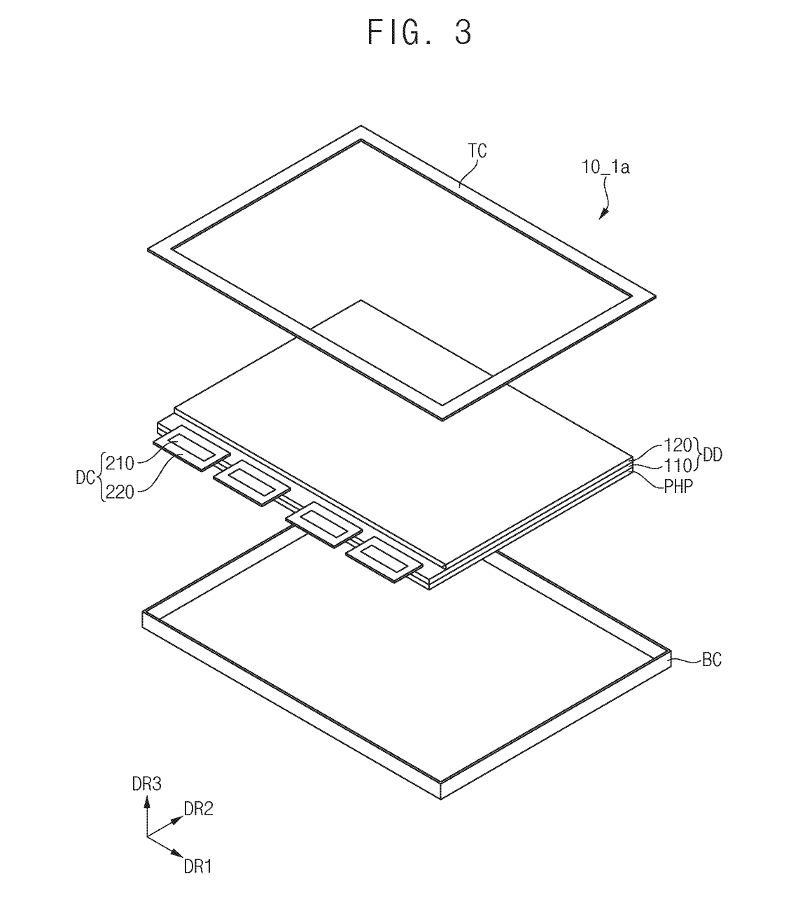

FIG. 3 is an exploded perspective view illustrating an electronic device according to one or more embodiments of the present disclosure.

Referring to FIG. 3, an electronic device according to one or more embodiments (e.g., the smartphone 10_1a) may include a display device DD, a heat-dissipating device PHP, and an outer case accommodating them.

In one or more embodiments as described with reference to the drawings, the first direction DR1, the second direction DR2, and the third direction DR3 may cross each other. For example, the first direction DR1, the second direction DR2, and the third direction DR3 may be normal (e.g., perpendicular) to each other.

For example, a plane may be defined by the first direction DR1 and the second direction DR2. A normal direction of the plane (e.g., a direction of a thickness of the display device DD) may be the third direction DR3.

Here, “top”, “upper”, and “upper surface” may refer to a direction in which a second substrate 120 is arranged relative to a first substrate 110 of the display device DD, i.e., in the third direction DR3. “Bottom”, “ground,” “base”, and “lower surface” may refer to a direction in which the heat-dissipating device PHP is arranged relative to the first substrate 110 of the display device DD, i.e., an opposite direction to the third direction DR3.

Also, in a plan view, “left”, “right”, “up”, “down” may refer to the direction of the display device DD relative to the plan view. For example, “right” may refer to the first direction DR1, “left” may refer to the opposite direction to the first direction DR1, “up” may refer to the second direction DR2, and “down” may refer to the opposite direction to the second direction DR2.

In one or more embodiments, the outer case may include an upper cover TC arranged on the upper part of the display device DD and a lower cover BC arranged on the lower part of the display device DD.

The upper cover TC may be positioned to cover an edge of the upper surface. The display device DD may include a display area in which a plurality of pixels is arranged. The display area may be surrounded by a peripheral area. For example, the upper cover TC may cover the display area.

The lower cover BC may be positioned to cover an entire lower surface. The display device DD may be connected to a drive chip DC. For example, the drive chip DC may include a drive circuit 210 and a flexible film 220. The flexible film 220 may be bent so that the drive circuit 210 may be adjacent to a back of the display device DD. For example, a surface on which a light emitted from the plurality of pixels is displayed as an image may be a front, and a surface facing in (e.g., opposite to) the third direction DR3 to the front may be a back. The front may be adjacent to the upper cover TC, and the back may be adjacent to the lower cover BC.

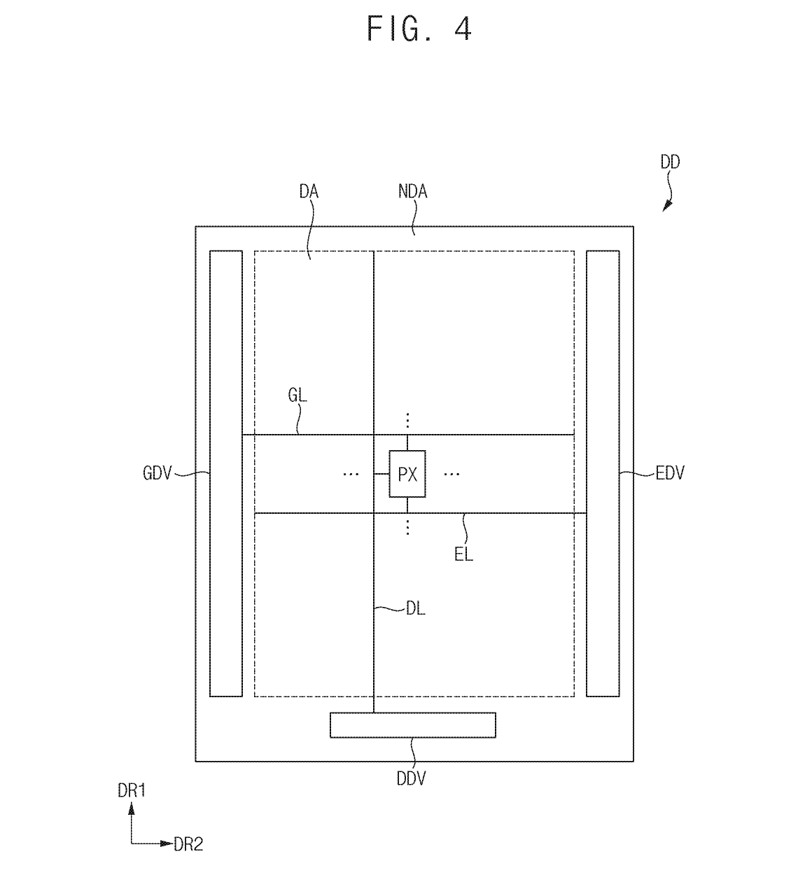

In the outer case, a seating groove may be defined. An object to be protected may be accommodated in a space defined by the seating groove. For example, the object to be protected may be the display device DD. In another example, the object to be protected may be any of a variety of electronic devices including the display device DD. FIG. 4 uses the smartphone 10_1a as an example, however, the present disclosure is not limited thereto. As described above, the electronic devices EA may be implemented in one or more suitable forms.

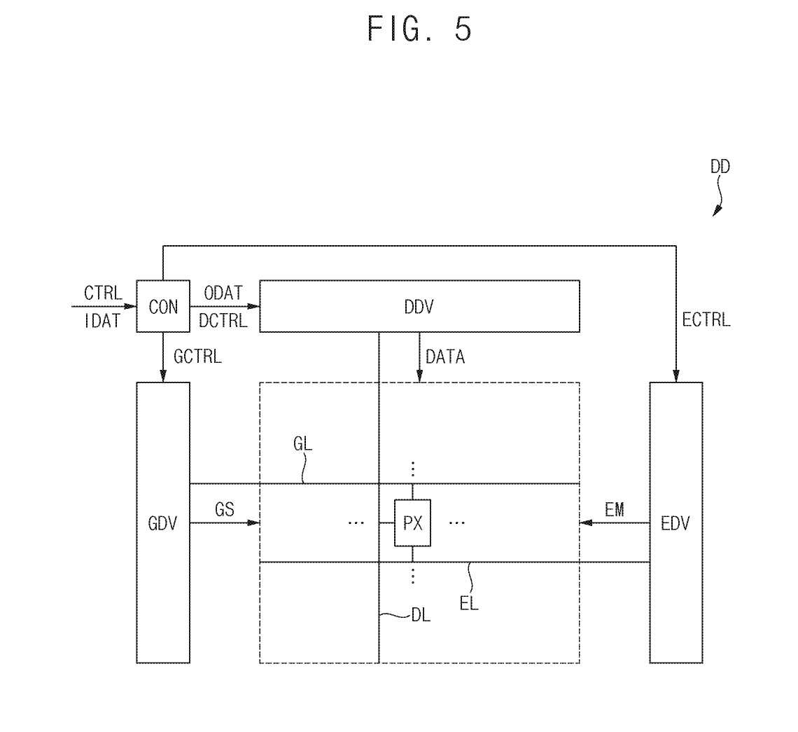

FIG. 4 is a plan view illustrating a display device of FIG. 3, according to one or more embodiments of the present disclosure. FIG. 5 is a block diagram illustrating the display device of FIG. 3, according to one or more embodiments of the present disclosure.

Referring to FIGS. 3, 4 and 5, the display device DD may include the display area DA and a non-display area NDA (i.e., the peripheral area).

The display area DA may be an area that displays the image. A plurality of pixels PX may be arranged in the display area DA. As the pixels PX are to emit light, the display area DA may display the image.

The non-display area NDA may be an area that does not display the image. The non-display area NDA may be around (e.g., surround) at least a portion of the display area DA. For example, the non-display area NDA may entirely surround the display area DA. A driver that provides a signal or a voltage to the pixels PX may be arranged in the non-display area NDA. For example, the driver may include a gate driver GDV, a light-emitting driver EDV, a data driver DDV, and a controller CON.

Each of the pixels PX may be electrically connected to the gate driver GDV, the light-emitting driver EDV, and the data driver DDV. For example, each of the pixels PX may be connected to the gate driver GDV through a gate line GL, may be connected to the light-emitting driver EDV through a light-emitting line EL, and may be connected to the data driver DDV through a data line DL. Accordingly, each of the pixels PX may receive a gate signal GS, a light-emitting signal EM, and a data voltage DATA.

The gate driver GDV may receive a gate control signal GCTRL from the controller CON. The gate driver GDV may generate the gate signal GS based on the gate control signal GCTRL. The gate signal GS may be provided to each of the pixels PX through a gate line GL (e.g., each pixel PX receives a gate signal GS via a respective gate line GL of the plurality of gate lines GL connected to the plurality of pixels PX).

The light-emitting driver EDV may receive a light-emitting control signal ECTRL from the controller CON. The light-emitting driver EDV may generate the light-emitting signal EM based on the light-emitting control signal ECTRL. The light-emitting signal EM may be provided to each of the pixels PX through the light-emitting line EL (e.g., each pixel PX receives a light-emitting signal EM via a respective light-emitting line EL of the plurality of light-emitting lines EL connected to the plurality of pixels PX).

The data driver DDV may receive a data control signal DCTRL and output image data ODAT from the controller CON. The data driver DDV may generate the data voltage DATA based on the data control signal DCTRL and the output image data ODAT. The data voltage DATA may be provided to each of the pixels PX through the data line DL (e.g., each pixel PX receives a data voltage DATA via a respective data line DL of the plurality of data lines DL connected to the plurality of pixels PX).

The controller CON may receive a control signal CTRL and input image data IDAT from an external device (e.g., the GPU). The controller CON may generate the gate control signal GCTRL, the light-emitting control signal ECTRL, the data control signal DCTRL, and the output image data ODAT based on the control signal CTRL and the input image data IDAT. The controller CON may control the gate driver GDV, the light-emitting driver EDV, and the data driver DDV.

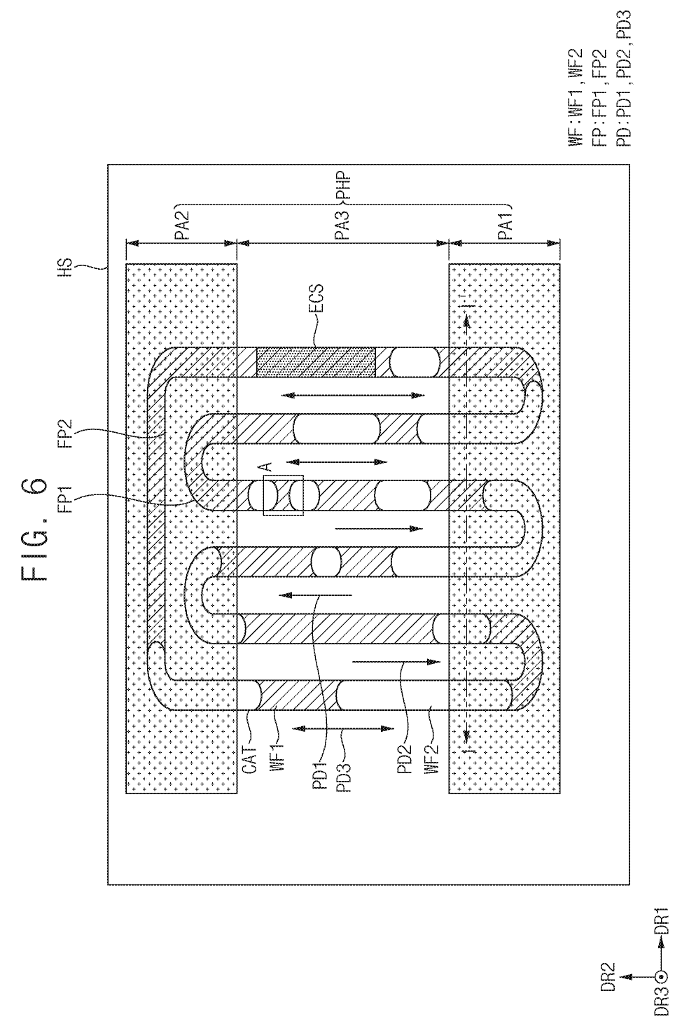

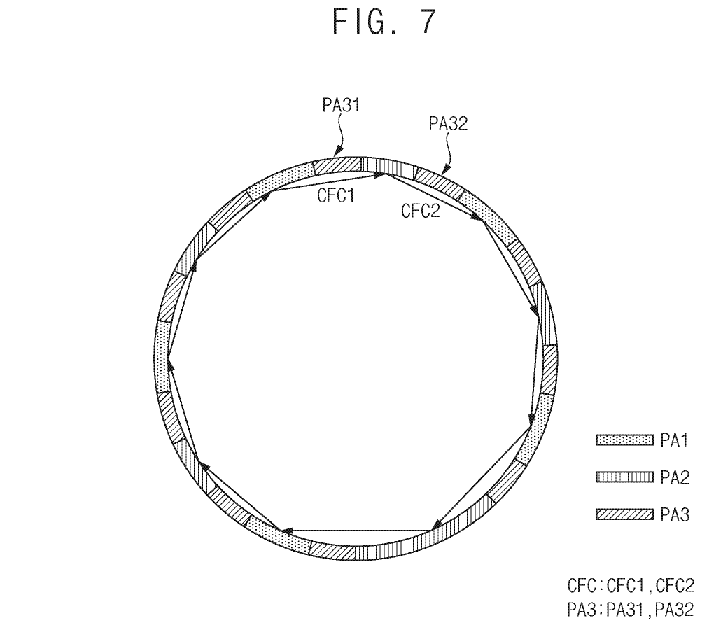

FIG. 6 is a plan view of a heat-dissipating device, according to one or more embodiments of the disclosure. FIG. 7 schematically shows a flow path FP of the heat-dissipating device of FIG. 6, according to one or more embodiments of the disclosure.

For example, FIG. 6 is a plan view of a heat-dissipating device PHP, and FIG. 7 schematically shows a flow path FP of the heat-dissipating device of FIG. 6 unfolded into a single annular shape.

In one or more embodiments, the heat-dissipating device PHP may include a working fluid WF and a capillary CAT filled with the working fluid.

For example, the heat-dissipating device PHP may include a first plate, the capillary CAT, and a second plate.

For example, the first plate may define an overall outline of the heat-dissipating device PHP. The first plate may be a flat plate, although the present disclosure is not limited thereto and the shape of the first plate may be any suitable shape generally available and/or generally utilized.

For example, the first and second plates may include a metal or a polymer resin. Examples of the metal may include aluminum (Al), zinc (Zn), tin (Sn), lead (Pb), copper (Cu), stainless steel, titanium (Ti), and/or the like. These metals may be used alone or in combination with each other. Examples of the polymer resin are polyethylene (PE), polycarbonate (PC), polypropylene (PP), polytetrafluoroethylene (PTFE), and/or the like. Accordingly, the first plate may be flexible and bend easily. However, the present disclosure is not limited thereto.

The working fluid WF may be injected into the capillary CAT. Examples of the working fluid WF may include water (H₂O), ammonia (NH₃), methanol (CH₃OH), ethanol (C₂H₅OH), individual halocarbon compounds, and/or the like. However, the present disclosure is not limited thereto. For example, the working fluid WF may also include a refrigerant, and/or the like.

The capillary CAT may be formed in the first plate. For example, the capillary CAT may be formed on or in an upper surface of the first plate. For example, the capillary CAT may be formed by patterning (e.g., etching) the first plate using a photoresist. However, the present disclosure is not limited thereto.

In some embodiments, the capillary may be formed in a shape of a capillary loop in which a thin tube is bent many times. The capillary may be a single closed-loop channel formed in a zigzag or spiral pattern. For example, the heat-dissipating device may have two or more loops.

An inner diameter (i.e., hydraulic diameter) of the capillary CAT may vary with a kind of the working fluid WF, for example, the inner diameter may be selected based on the working fluid WF used and/or selected. When the working fluid WF is water, the hydraulic diameter may be about 1 mm to about 6 mm, if (e.g., when) the working fluid is ethanol, the hydraulic diameter may be about 0.6 mm to about 3.2 mm. However, the present disclosure is not limited thereto. For example, the hydraulic diameter may vary depending on density of the working fluid WF, surface tension and/or the like.

In one or more embodiments, the capillary CAT may include a first capillary section and a second capillary section having different diameters from each other. For example, the first capillary section may have a first diameter and a second capillary section may have a second diameter smaller than the first diameter. As the second capillary section has the smaller diameter, a capillary-force acting on the liquid phase of the working fluid may increase. For example, the capillary-force may be defined as a product of a length of the flow path FP and the surface tension of the working fluid WF. However, the present disclosure is not limited thereto. For example, the capillary CAT may have a same diameter depending on a location, or may be formed to have three or more different diameters.

The second plate may be arranged on one side of the first plate. For example, the second plate may be laminated on the upper surface of the first plate. For example, the second plate may be bonded to the first plate. If (e.g., when) the second plate is bonded to the upper surface of the first plate, the second plate may cover the capillary CAT. For example, the second plate may seal the capillary CAT.

However, the present disclosure is not limited thereto. For example, the heat-dissipating device PHP may have one or more suitable structures. For example, the capillary CAT may be formed between the first and second plates, or in the second plate while the first plate covers the second plate.

The capillary CAT may provide the flow path for the working fluid WF. After the capillary CAT is evacuated, the working fluid WF may be injected. In one or more embodiments, a liquid phase (liquid slug) and a vapor phase (vapor plug) may be positioned alternatively in the working fluid WF. The liquid phase working fluid WF1 and the vapor phase working fluid WF2 may be positioned alternatively along an axis of the capillary. The working fluid WF in the capillary CAT, a slug-train unit including (e.g., consisting of) the liquid phase working fluid WF1 and the vapor phase working fluid WF2, may be formed under surface-tension effects.

At opposite ends of the capillary bundle may be a first section PA1 (i.e., an evaporation section, e.g., where the working fluid WF is more likely to be evaporated) and a second section PA2 (i.e., a condensation section, e.g., where the working fluid WF is more likely to be condensed into a liquid). Inside the flow path FP defined by the capillary CAT, the working fluid WF may move. However, the present disclosure is not limited thereto.

For example, the first section PA1 and the second section PA2 may be defined based on a liquid ratio inside the flow path FP according to an operation of the heat-dissipating device PHP. For example, the ratio of the working fluid WF filled in the flow path FP during manufacture may be referred to as an average filling ratio (unit: vol%). A relatively hot part (a part where the heat source is located) may have a liquid ratio in the flow path FP lower than an average filling ratio due to evaporation of the working fluid WF. A part having a relatively low liquid ratio may be defined as the first section PA1. In contrast, a relatively less hot part may have a liquid ratio greater than the average filling ratio due to condensation of the working fluid WF. A part having a relatively large liquid ratio in the flow path FP may be defined as the second section PA2.

In one or more embodiments, the first section PA1 may be a section that absorbs heat generated from the heat source HS. The heat of the evaporation section PA1 may be transferred to the working fluid WF as latent heat of vaporization. The liquid working fluid WF1 may be to absorb external heat and vaporize. The gaseous working fluid WF2 may expand due to a vaporization pressure.

In one or more embodiments, the second section PA2 may be separated from the first section PA1. The second section PA2 may be a section that dissipates the heat absorbed by the first section PA1. In the condensation section PA2, the liquid working fluid WF1 may be condensed. The gaseous working fluid WF2 may be contracted by a condensing pressure.

In one or more embodiments, the third section PA3 may connect the first and second sections PA1, PA2. As shown in FIG. 7, the third section PA3 may include a 3-1 subsection PA31 that guides the working fluid WF from the first section PA1 to the second section PA2 and a 3-2 subsection PA32 that guides the working fluid WF from the second section PA2 to the first section PA1.

Because of a temperature difference between the evaporation section PA1 and the condensation section PA2, the working fluid WF may vaporize in the evaporation section PA1 and condense in the condensation section PA2. The resulting pressure difference between the evaporation pressure and the condensation pressure of the two ends (i.e., the evaporation section and the condensation section) may cause reciprocating oscillation PD3 of the slug-train unit (i.e., reciprocating oscillation of the working fluid WF). As the heat input provided to the capillary CAT increases, the slug-train unit may move cyclically in one direction (e.g., the first flow direction PD1 and the second flow direction PD2). Through the oscillation and the cyclical movement, the heat-dissipating device PHP may transfer the heat from the evaporation section PA1 to the condensation section PA2 (i.e., the heat may be dissipated).

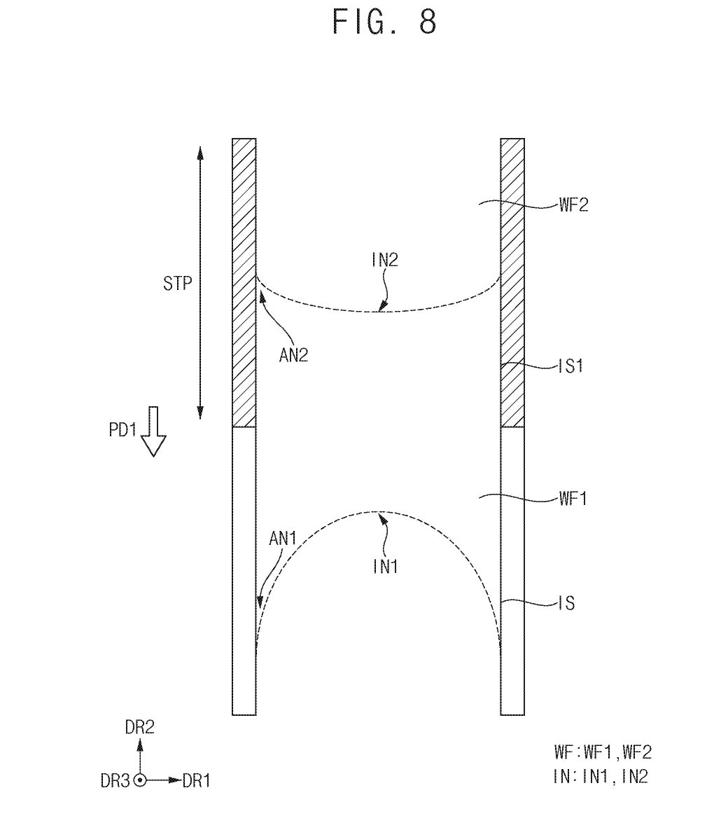

In one or more embodiments, the heat-dissipating device PHP may include a capillary-force controller CFC located in the third section PA3. The capillary-force controller CFC may be configured to increase or decrease capillary-force such that the working fluid WF absorbing the heat in the first section PA1 moves to the second section PA2 and the working fluid WF releasing the heat in the second section PA2 moves to the first section PA1. For example, the capillary-force controller CFC may include a first capillary-force controller CFC1 and a second capillary-force controller CFC2. The capillary-force controller CFC may be an artificial control device that control the flow direction PD (e.g., the flow of the working fluid WF in the first flow direction PD1, the second flow direction PD2, and/or the third flow direction PD3). Detailed descriptions of the capillary-force controller CFC are provided below with reference to FIGS. 8 to 14.

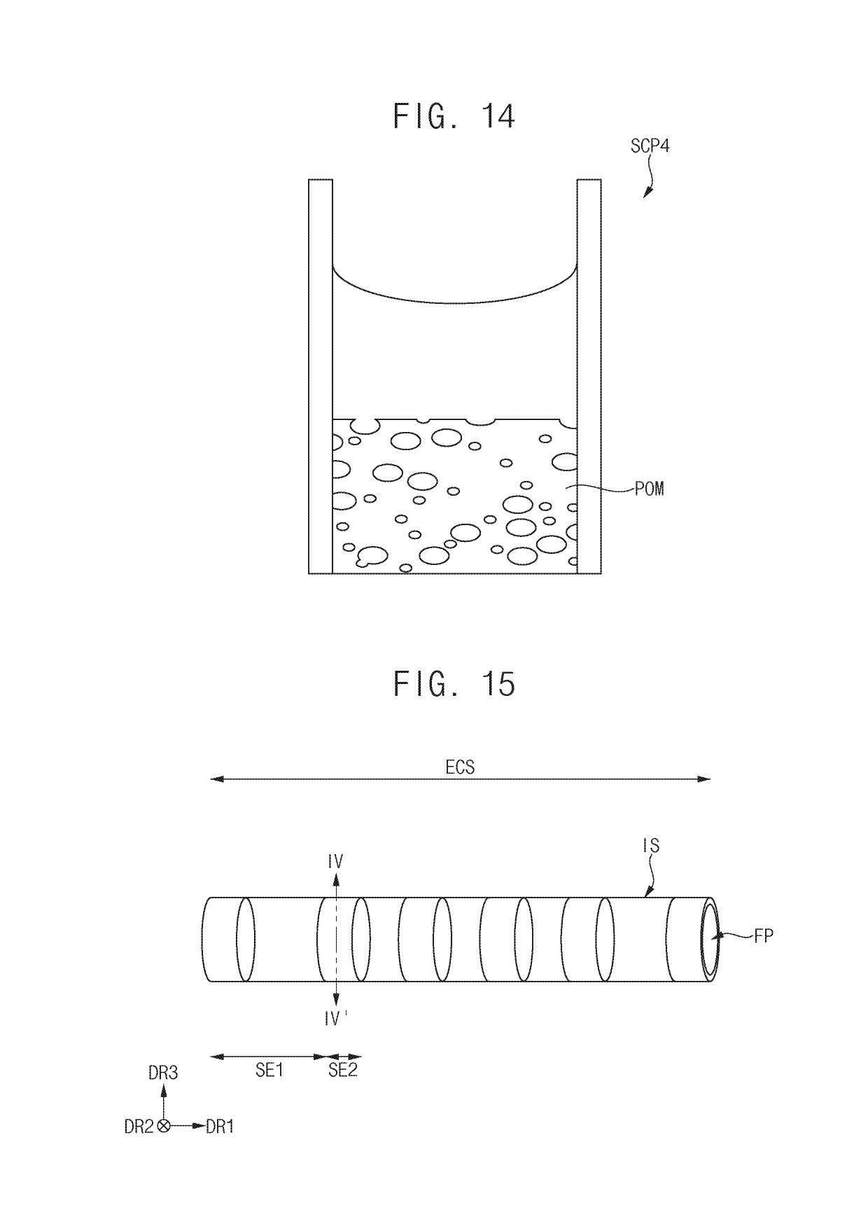

In one or more embodiments, the heat-dissipating device PHP may include a surface-energy-change section ECS provided on a portion of the inner surface of the flow path FP (e.g., at the inner surface of the capillary CAT). The surface-energy-change section ECS may include a first zone having a first surface energy and a second zone having a second surface energy different from the first surface energy where the first and second zones alternate with each other. The surface-energy-change section ECS may be a device that induces bubble destruction into a liquid column by alternately arranging surfaces with different wettability. Detailed descriptions of the surface-energy-change section ECS are provided below with reference to FIGS. 15 to 23.

The inner surface of the flow path FP may be inspected either destructively or non-destructively. For example, the inner surface of the flow path FP may be inspected with a physical/chemical treatment using a magnetic-particle inspection, a radiographic inspection, an ultrasonic inspection, an eddy-current test, a dimensional measurement, a 3-D microscope, a probe microscope, a scanning electron microscope (SEM), a transmission electron microscope (TEM), or a focused ion beam (FIB) inspection, and/or the like.

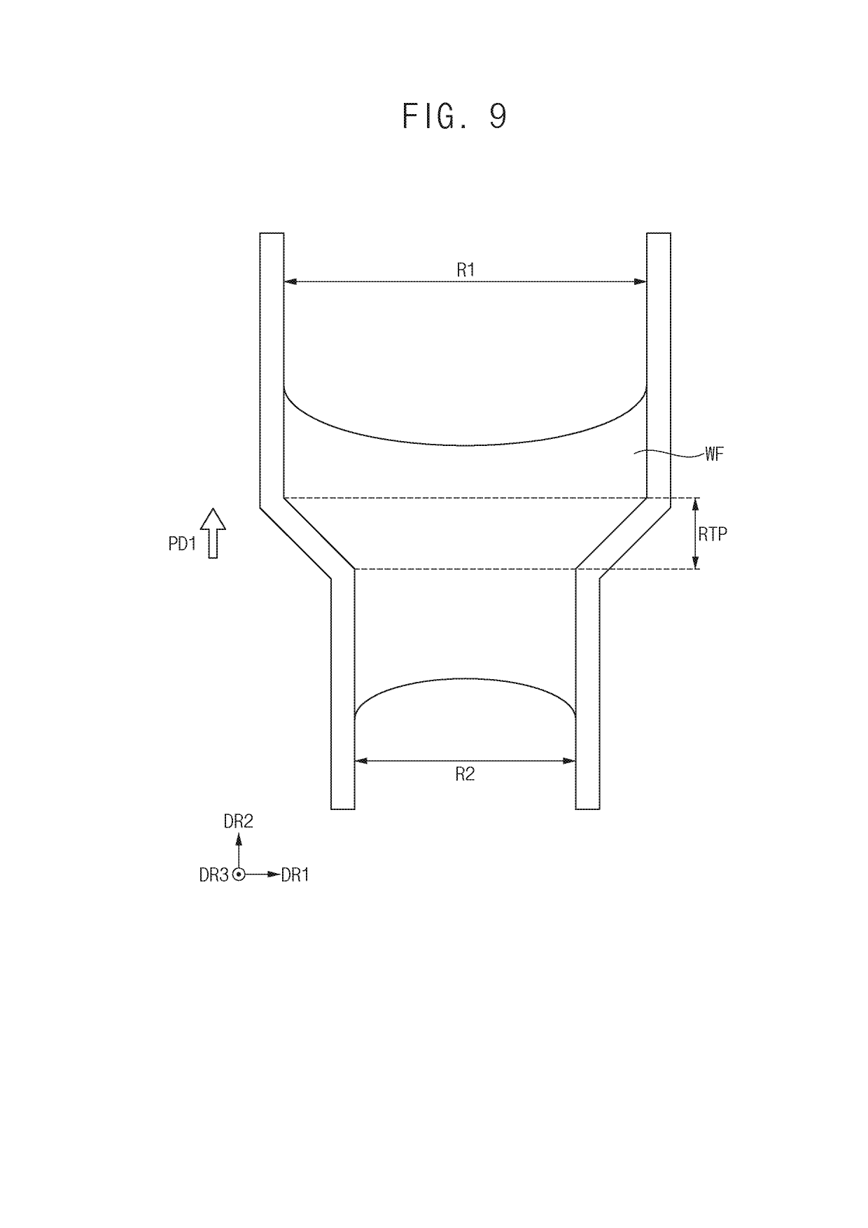

FIG. 8 is a cross-sectional view taken along a length of the capillary CAT at region A of FIG. 6, according to one or more embodiments of the disclosure. FIG. 9 is a cross-sectional view taken along a length of a portion of a capillary of a heat-dissipating device, according to one or more embodiments of the disclosure. FIGS. 8 and 9 are views illustrating the first capillary-force controller of FIG. 7 when region A of FIG. 6 is a 3-1 subsection PA31, according to one or more embodiments of the disclosure.

Referring to FIGS. 7, 8 and 9, in one or more embodiments, the capillary-force controller CFC may include a surface-treatment part STP having a surface energy greater in the 3-1 subsection PA31 than in the 3-2 subsection PA32.

In one or more embodiments, a contact angle defined by an interface IN between the liquid phase working fluid WF1 and the vapor phase working fluid WF2 at an inner surface IS of the flow path FP may be configured to decrease along the flow direction PD1 of the working fluid WF in the 3-1 subsection PA31. As the contact angle decreases, the capillary-force (i.e., heat flux) may decrease. For example, due to the surface-treatment unit STP, the contact angle may decrease along the flow direction PD1 from a second contact angle AN2 to a first contact angle AN1.

For example, the first contact angle AN1 may be defined by the inner surface IS of the flow path FP and an interface IN1 between the liquid phase working fluid WF1 and the vapor phase working fluid WF2.

The second contact angle AN2 may be defined by the inner surface IS1 of the surface-treatment part STP and an interface IN2 between the liquid phase working fluid WF1 and the vapor phase working fluid WF2 as the working fluid WF moves along the flow path FP (e.g., the interface IN2 between the liquid phase working fluid WF1 and the vapor phase working fluid WF2 at the inner surface IS of the surface-treatment part STP).

In one or more embodiments, contact angles AN1 and AN2 may be measured with a contact-angle goniometer.

For example, the surface-treatment part STP may be formed by one or more suitable methods, such as sand-blasting (a method of forming micro-roughness by physically colliding (e.g., by projecting) fine sand particles using compressed air with a surface of a substrate), sand-papering (a method of changing the surface of a substrate by rubbing the surface of the substrate with sandpaper), shot blasting (a method of changing the surface of the substrate by spraying fine particles of metal or non-metal called shot or grit), plasma etching (etching using gas plasma), acid/base etching (etching using acid/base solutions), discharge treatment (a method of melting and then re-solidifying the surface of the substrate by using high heat generated by electric discharge), laser treatment (a method of ablating the surface of the substrate by irradiating the surface of a substrate with a high-power laser pulse), and/or the like.

In one or more embodiments, as shown in FIG. 9, the capillary-force controller CFC may include a diameter-varying part RTP configured such that an inner diameter of the 3-1 subsection PA31 increases along a flow direction PD1 of the working fluid WF and an inner diameter of the 3-2 subsection PA32 decreases along the flow direction PD2 of the working fluid WF. For example, the inner diameter of the capillary may change from a first diameter R1 to a second diameter R2 (or vice versa) at the diameter-varying part RTP. As the diameter increases, the capillary-force (i.e., the heat flux) may decrease.

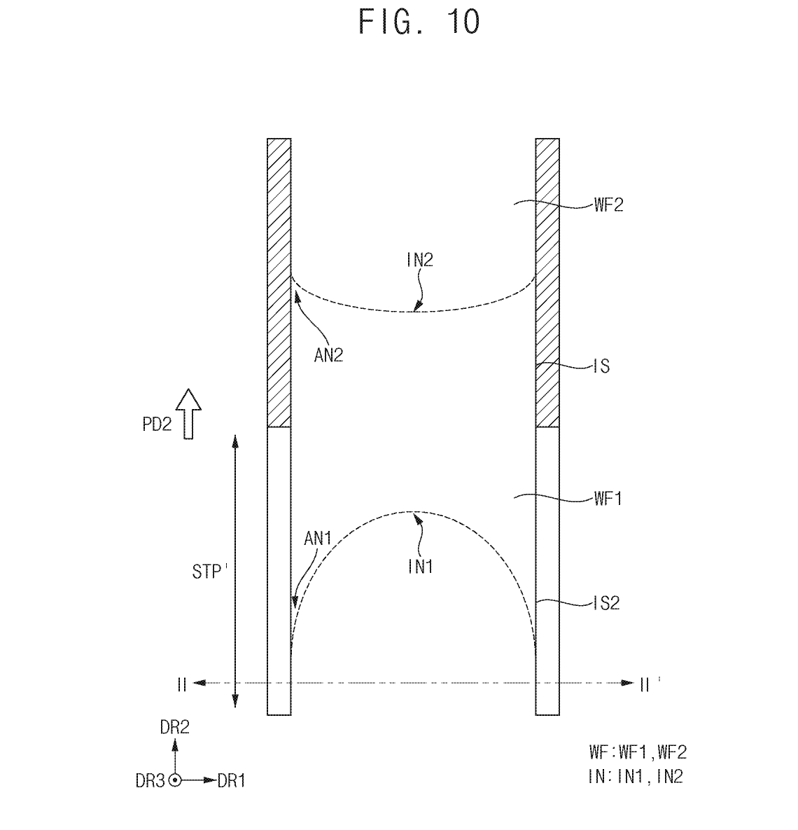

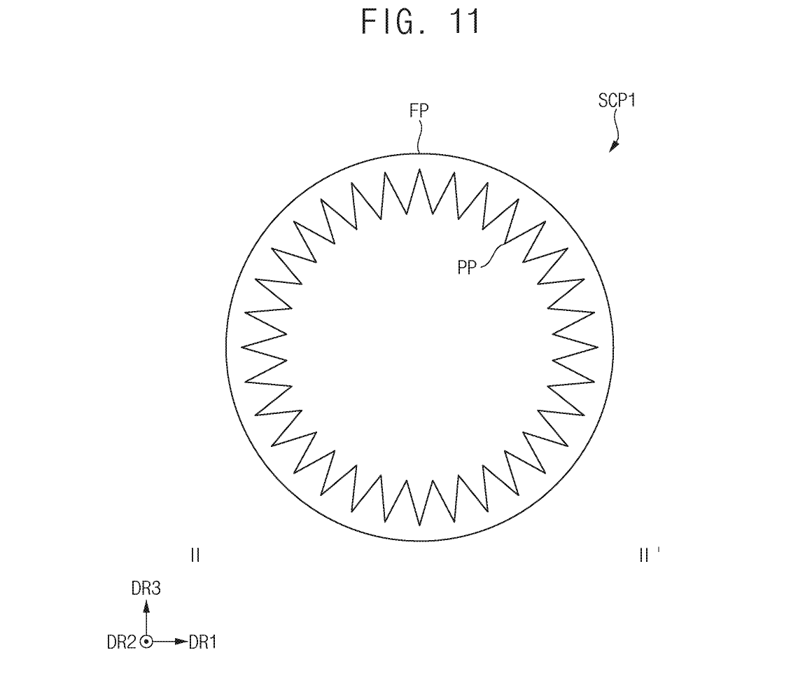

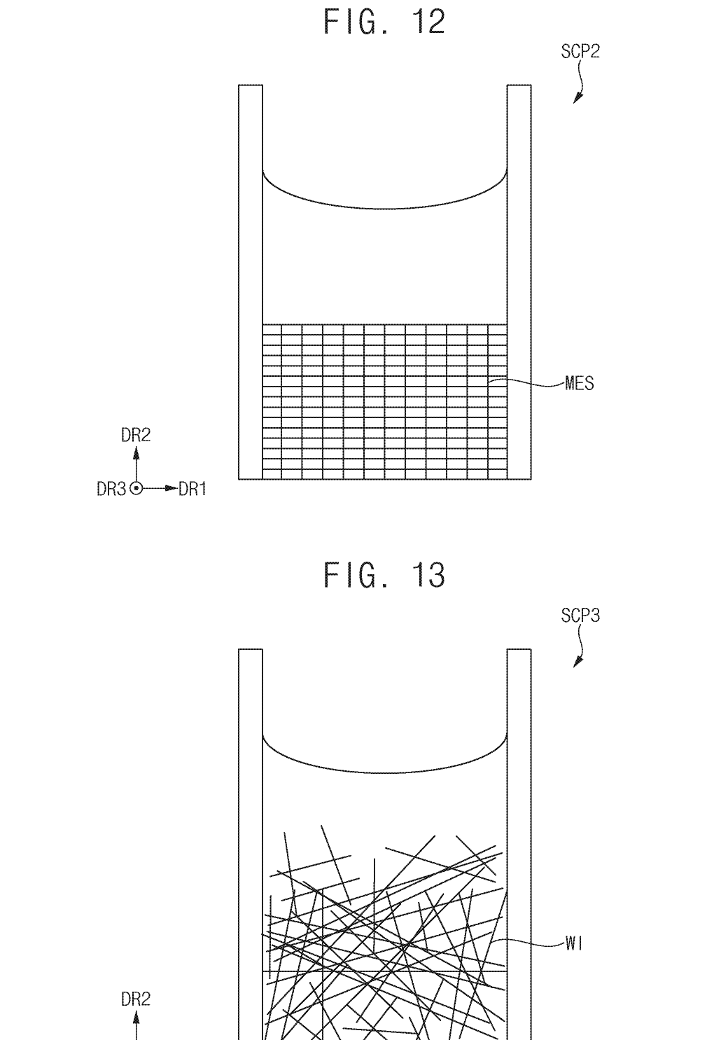

FIG. 10 is a cross-sectional view taken along a length of the capillary CAT at region A of FIG. 6, according to one or more embodiments of the disclosure. FIG. 11 is a cross-sectional view taken along the line II-II’ of FIG. 10, according to one or more embodiments of the present disclosure. FIGS. 12 – 14 are each a cross-sectional view taken along a length of a portion of a capillary CAT of a heat-dissipating device PHP, according to embodiments of the present disclosure.

FIGS. 10 – 14 are views illustrating a second capillary-force controller of FIG. 7 when region A of FIG. 6 is a 3-2 subsection PA32, according to one or more embodiments of the present disclosure.

Referring to FIGS. 7, and 10 to 14, in one or more embodiments, the capillary-force controller CFC may include a surface-treatment unit STP’ having the surface energy of the 3-1 subsection PA31 greater than the surface energy of the 3-2 subsection PA32. While FIGS. 11-14 are described with reference to the capillary-force controller CFC of the 3-2 subsection PA32, the surface-treatment units STP’ described with respect to FIGS. 11-14 are also applicable to the surface-treatment unit STP of the 3-1 subsection PA31 described above with reference to FIG. 8.

In one or more embodiments, the contact angle defined by an interface IN between the liquid phase working fluid WF1 and the vapor phase working fluid WF2 at an inner surface IS of the flow path FP may be configured to increase along the flow direction PD2 of the working fluid WF in the 3-2 subsection PA32. For example, due to the surface-treatment unit STP’, the contact angle may increase along the flow direction PD2 from the first contact angle AN1 to the second contact angle AN2.

In one or more embodiments, the capillary-force controller CFC may include a surface area modifier (e.g., SCP of FIG. 11, SCP2 of FIG. 12, SCP3 of FIG. 13, SCP of FIG. 14, and/or the like) such that a surface area of the inner wall of the 3-1 subsection PA31 is smaller than a surface area of the inner wall of the 3-2 subsection PA32 decreases along its length. For example, the capillary-force controller CFC may include the surface area modifier such that the surface area of the inner wall of the 3-1 subsection PA31 increases along its length and a surface area of the inner wall of the 3-2 subsection PA32 decreases along its length. For example, the surface-treatment unit STP, STP’ increases the surface area of the inner walls of the flow path FP at the surface-treatment unit STP, STP’.

As shown, for example, in FIG. 11, the surface area modifier SCP1 may include a protrusion PP protruding toward the inner surface of the flow path FP in the surface-treatment unit STP, STP’ of the 3-2 subsection PA32. The protrusion PP may reduce the contact angle of the working fluid WF. Accordingly, a heat transfer rate may be increased. For example, the protrusion PP may be formed by one or more suitable methods such as powder injection molding.

However, the present disclosure is not limited thereto. The capillary-force controller CFC may include one or more suitable components that may increase or decrease the capillary-force, as shown in FIGS. 12-14.

For example, in FIG. 12, the surface area modifier SCP2 may include a mesh net MES arranged in (inside) the surface-treatment unit STP, STP’ of the 3-2 subsection PA32 to increase surface area. As shown in FIG. 13, the surface area modifier SCP3 may include linear structures WI arranged in (inside) the surface-treatment unit STP, STP’ of the 3-2 subsection PA32 to increase surface area. As shown in FIG. 14, the surface area modifier SCP4 may include a porous material POM arranged in the surface-treatment unit STP, STP’ of the 3-2 subsection PA32 to increase surface area. The mesh net MES, the line structures WI, the porous material POM may increase heat dissipation performance by thinning a thickness of a liquid film on the inner surface of the flow path FP. As the surface area increases, the capillary-force (i.e., the heat flux) may increase. However, the disclosure is not limited thereto. The surface area modifier SCP2, SCP3, SCP4 may also be arranged in the 3-1 subsection PA31. Even in this case, the surface area of the 3-2 subsection PA32 may be greater than the surface area of the 3-1 subsection PA31.

However, the above are examples and the present disclosure is not limited thereto. For example, the heat-dissipating device PHP may further include one or more suitable components that increase the capillary-force. For example, similar to what was described above with reference to FIGS. 8 and 9, it may be configured to have the smaller contact angle (through surface-treatment) or the smaller diameter.

FIGS. 15, 16, 17 and 18, are views illustrating a heat-dissipating device according to one or more embodiments of the disclosure.

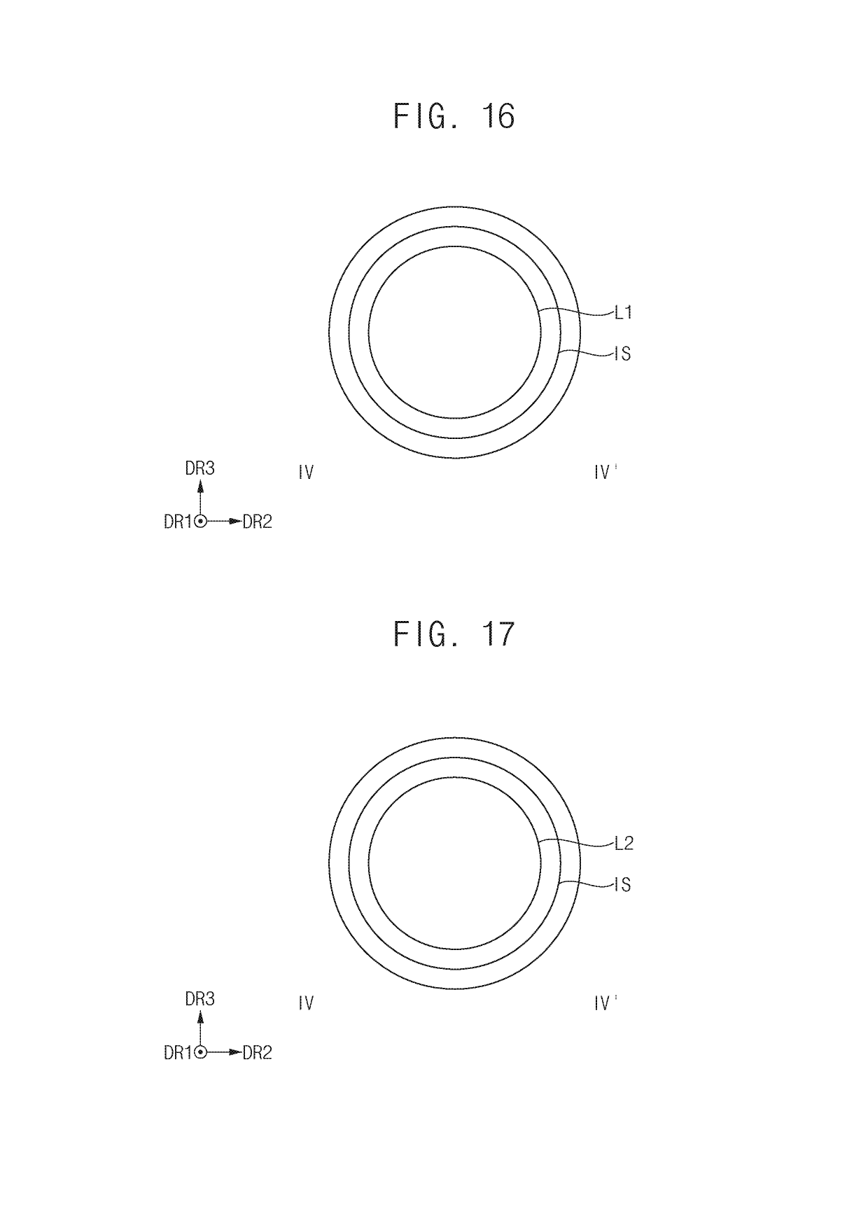

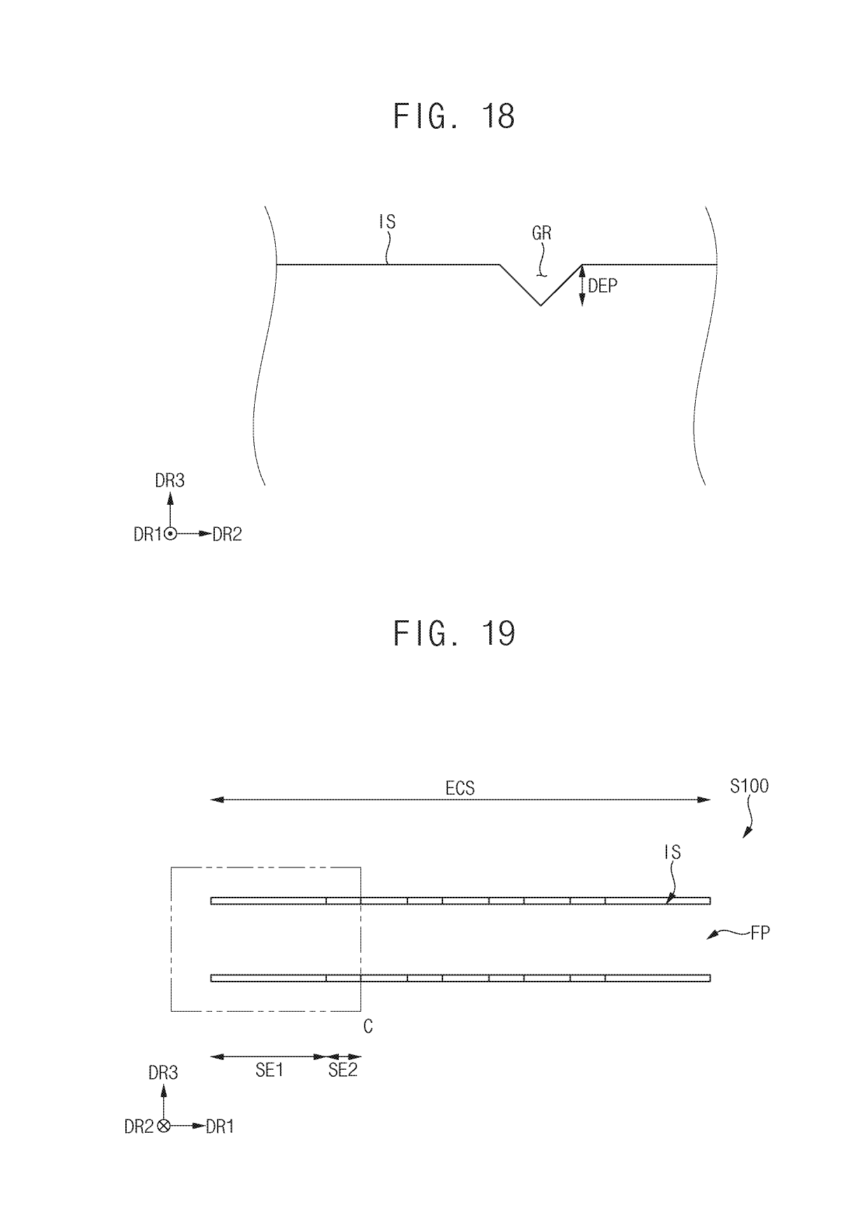

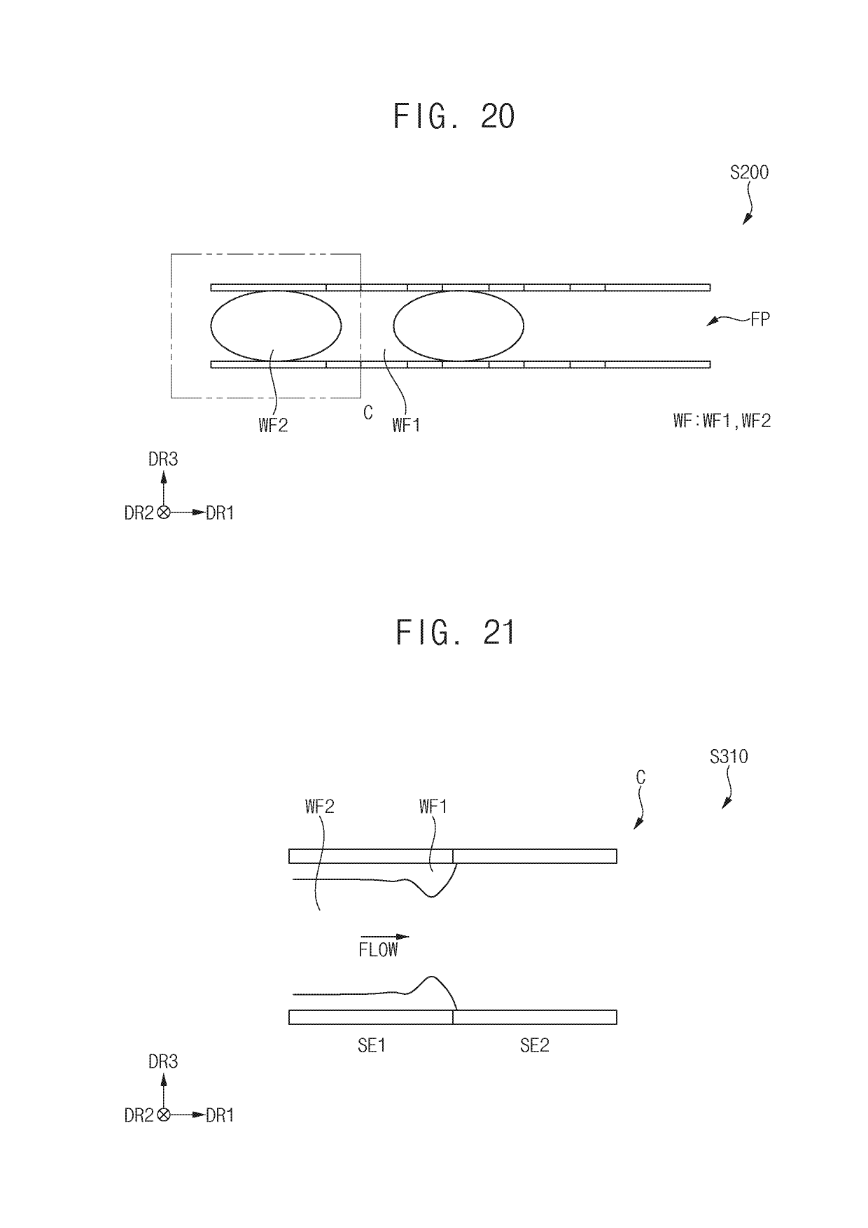

For example, FIG. 15 illustrates a portion of the surface-energy-change section of FIG. 6, according to embodiments of the present disclosure. FIG. 16 is a cross-sectional view taken along the line IV-IV’ of FIG. 15, according to embodiments of the present disclosure. FIG. 17 is a cross-sectional view taken along the line IV-IV’ of FIG. 15, according to embodiments of the present disclosure. FIG. 18 is a schematic view illustrating a groove formed on the inner surface of the flow path of FIG. 15, according to embodiments of the present disclosure.

Referring to FIGS. 3, 6, 15 to 18, in one or more embodiments, an electronic apparatus EA may include a surface-energy-change section ECS provided on a portion of the inner surface IS of the flow path FP, the surface-energy-change section ECS including a first section SE1 having a first surface energy and a second section SE2 having a second surface energy different from the first surface energy where the first and second zones SE1, SE2 alternate with each other.

Vibration due to dry-out in the flow path FP of the heat-dissipating device PHP may occur. Dry-out refers to a phenomenon in which, in a two-phase flow, the inner surface IS of the flow path FP may no longer be in contact with the liquid phase working fluid WF1, and the thin liquid film flowing along the inner surface IS is broken, thereby drying the inner surface IS of the flow path FP. For example, dry-out refers to a phenomenon in which the liquid phase working fluid WF1 and the vapor phase working fluid WF2 alternately contact the inner surface IS of the flow path FP. A heat transfer coefficient of the inner surface IS of the flow path FP may decrease from a wet state to a dry-wet state. Accordingly, a temperature of the inner surface IS may increase as a result of dry-out.

When the vibration due to the above-described dry-out occurs, the temperature of the inner surface IS of the flow path FP may oscillate to maintain the heat flux as the heat transfer coefficient of the inner surface IS of the flow path FP oscillates between the wet state and the dry-wet state. Accordingly, a periodic thermal stress change may occur, which may lead to damage to the heat-dissipating device PHP.

To prevent or reduce this, in one or more embodiments, the heat-dissipating device PHP may include the surface-energy-change section ECS in which the first section SE1 having the first surface energy and the second section SE2 having the second surface energy different from the first surface energy are alternately positioned on the inner surface IS of the flow path FP.

In one or more embodiments, the surface-energy-change section ECS may be formed by alternately arranging materials having different surface energies. In one or more embodiments, the surface-energy-change section ECS may be alternately positioned by using a surface-treatment technique to have sections having different surface energies. In one or more embodiments, the surface-energy-change section ECS may be arranged at at least one location during one rotation from the section where the working fluid WF1 is introduced to the section where it is discharged.

In the first section SE1, the liquid phase working fluid WF1 may flow in a form of the liquid film along the inner surface IS of the flow path FP. In the first section SE1, the vapor phase working fluid WF2 may flow along a center of the flow path FP.

In one or more embodiments, the inner surface of the first section SE1 may be hydrophilic, and the inner surface of the second section SE2 may be hydrophobic. For example, if (e.g., when) the heat-dissipating device PHP may be formed of a hydrophilic metal, and/or surface-treatment using the hydrophobic material may be performed only on the second section SE2.

The contact angle AN may be defined if (e.g., when) the working fluid WF is in thermodynamic equilibrium with the inner surface IS. The contact angle may vary depending on the properties of the working fluid WF, the shape of the inner surface, and/or the like.

For example, the contact angle between the hydrophilic inner surface and the working fluid WF may be about 8 degrees, and the contact angle between the hydrophobic inner surface and the working fluid WF may be about 160 degrees. The higher the surface energy (i.e., the higher the wettability), the more the working fluid WF may come into contact with the hydrophilic inner surface (e.g., the contact angle AN may be smaller). In such embodiments, more evaporation may be induced in the evaporation section PA1, so that the heat dissipation performance may be further improved.

In one or more embodiments, the surface-energy-change section ECS may include a surface-treatment layer L1 (see, e.g., FIG. 16). The surface-treatment layer L1 may be a layer treated with at least one of plasma, ozone, and ultraviolet rays. For example, the surface-treatment layer L1 may be surface treated with plasma, ozone, ultraviolet rays, and/or the like to provide a region (e.g., second section SE2) that is surface treated to be hydrophobic. For example, the surface-treatment layer L1 may be formed by one or more suitable methods, such as patterning with a hydrophobic structure.

In one or more embodiments, the surface-energy-change section ECS may include a coating layer L2 (see, e.g., FIG. 16). The coating layer L2 may be formed of a material having a hydrophobic material. In one or more embodiments, the coating layer L2 may be formed of a fluorine resin, a fluorine-based silane coupling agent, a fluorine-based isocyanate compound, an alkanethiol, an organo-silane compound, a fatty acid, an aromatic azide compound, and/or the like. These may be used alone or in combination with each other. For example, the coating layer L2 may be formed by thinly coating the inner surface of the flow path FP with the hydrophobic material. However, the present disclosure is not limited thereto. The coating layer L2 may also be formed by using a chemical bond (e.g., covalent bond) between the hydrophobic material and a metal surface. However, the present disclosure is not limited thereto.

As shown in FIG. 18, in one or more embodiments, a shape of the groove GR (e.g., a depth DEP, and/or the like) may be adjusted to make the inner surface IS of the flow path FP have hydrophobic/hydrophilic properties.

For example, if (e.g., when) the groove GR is formed on a micro scale or less, a height difference (e.g., the depth DEP) between a portion corresponding to a mountain and a portion corresponding to a valley is relatively small, and air may be included between the mountain and the valley to minimize or reduce the contact angle CN with the fluid. Accordingly, the inner surface IS of the flow path FP in which the groove GR is formed may have hydrophobic properties.

For another example, if the groove GR is formed on a millimeter scale or larger or linearly, the inner surface of the flow path FP may have hydrophilicity.

For example, physical grooves may be formed by sanding, CNC, laser, and/or the like. For another example, chemical grooves may be formed using one or more suitable etchants.

In one or more embodiments, surface-treatment may be performed not only on the second section SE2 but also on the first section SE1. For example, the coating layer may be formed on the first section SE1 using the hydrophilic material (e.g., a material having an -OH group).

It may be difficult to determine the location or locations in which dry-out may occur. Therefore, the surface-energy-change section ECS may be positioned at any location in the heat-dissipating device PHP. For example, in FIG. 6, it is described as being positioned at the third section PA3; however, the disclosure is not limited thereto. For example, the surface-energy-change section ECS may be positioned at the first section PA1 or the second section PA2.

If the entire inner surface of the flow path FP is coated with the hydrophobic material, it may create resistance between the hydrophilic fluid and the inner surface, which may result in the decrease in heat dissipation performance. Therefore, only the portion (e.g., the second of the flow path FP may be formed to have hydrophobicity.

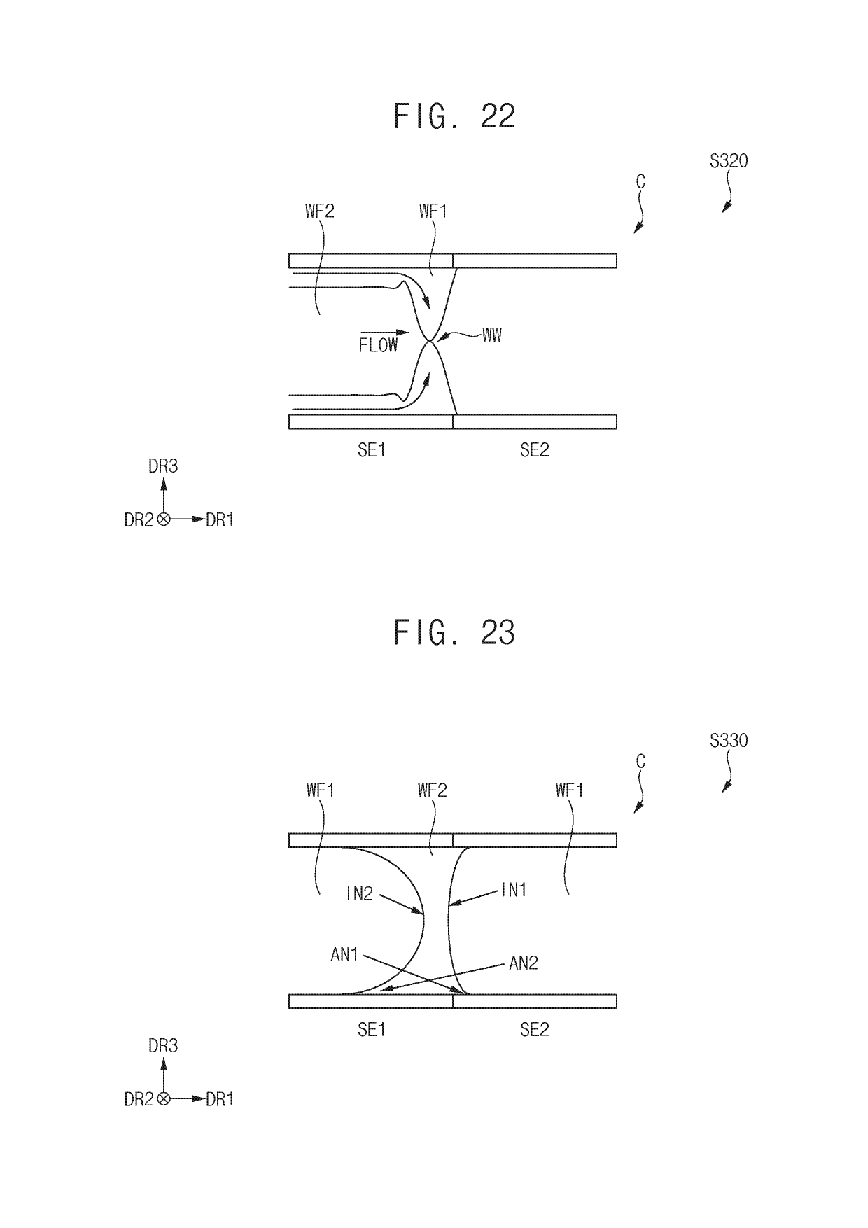

The occurrence of dry-out due to clumping of the vapor phase working fluid WF2 may be prevented or reduced by the collapse of the bubble. Detailed descriptions thereof are provided in more detail below with reference to FIGS. 19 to 23.

However, the below are examples and the present disclosure is not limited thereto. For example, the cross-section of the tube may have one or more suitable shapes such as circular or square.

FIGS. 19 to 23 are cross-sectional views of the capillary CAP of the heat-dissipating device PHP of FIG. 6 illustrating a heat-dissipation method of an electronic device using the heat-dissipating device PHP, according to one or more embodiments. FIGS. 21 to 23 are each a cross-sectional view of region C of FIGS. 19-20, according to one or more embodiments of the present disclosure.

A heat-dissipating method of the electronic device according to one or more embodiments of the present disclosure may include forming, on the portion of the inner surface IS of the flow path FP, the surface-energy-change section ECS including the first zone SE1 (e.g., a hydrophilic section) and the second zone SE2 (e.g., hydrophobic section) that alternate with each other, the first zone SE1 having the first surface energy, and the second zone SE2 having the second surface energy lower than the first surface energy (S100), charging the flow path FP with the working fluid WF (S200), and dissipating heat from the heat source while the working fluid WF travels through the flow path FP.

The liquid phase working fluid WF1 may flow along the inner surface IS of the hydrophilic section in a liquid film form.

In one or more embodiments, in the step (e.g., act or task) of dissipating the heat from the heat source while the working fluid WF travels through the flow path FP, the flow of the liquid phase working fluid WF1 may stop at the interface between the first section SE1 and the second section SE2. In the hydrophobic section, the flow of the liquid phase working fluid WF1 may be stopped by friction (S310). The liquid phase working fluid WF1 may form a liquid column WW due to the surface tension at the interface between the first section SE1 and the second section SE2. As the thickness of the liquid film gradually becomes thicker, the liquid column WW may be formed by coagulation due to the surface tension (S320). The liquid column WW may reduce the size of the vapor phase working fluid WF2. The liquid column WW may block or reduce the flow path FP to collapse the bubble. As the size of the bubble decreases, the occurrence of dry-out may be prevented or reduced (S330). The inner diameter IS of the flow path FP may be formed to a size that may form the liquid column WW.

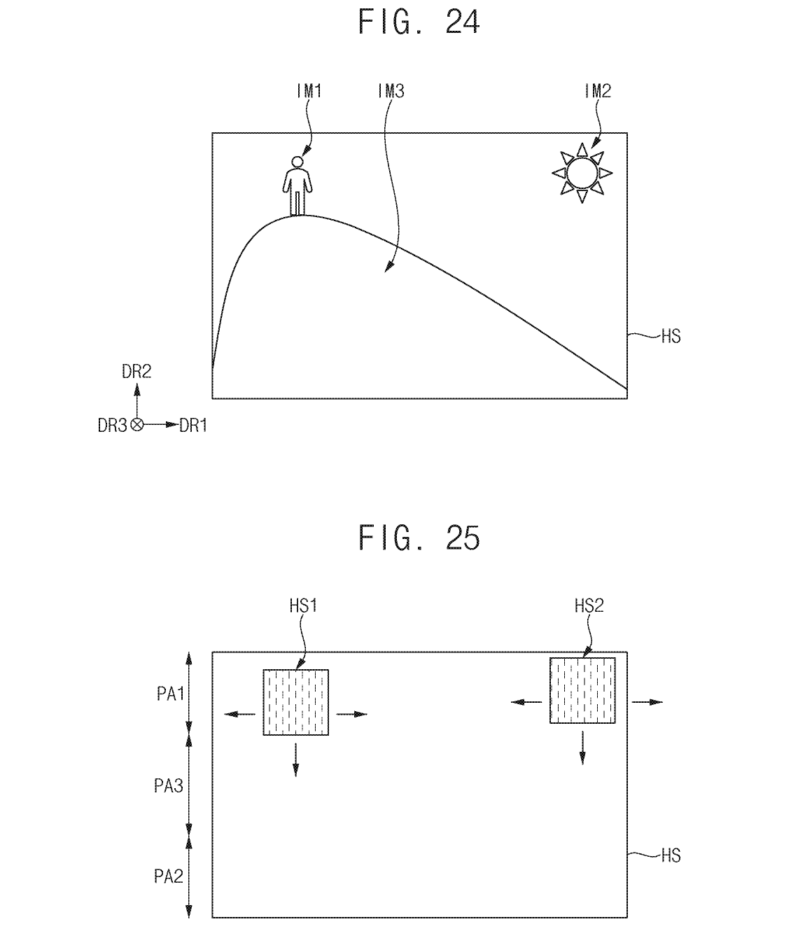

FIGS. 24 and 25 are schematic views illustrating the heat source associated with the heat-dissipating device of FIG. 6, according to one or more embodiments.

Referring to FIGS. 3, 6, 24 and 25, in one or more embodiments, a heating source HS may be any one of a display device DD including a plurality of pixels PX, an electronic device 10 including the display device DD and an outer case TC, BC accommodating the display device DD.

For example, a first image IM1, a second image IM2, and a third image IM3 may be displayed on the display device DD. The second image IM2 may be to emit a color that is relatively closer to white than the first image IM1. The third image IM3 may be to emit a color that is closer to black, the darkest color. In such embodiments, as illustrated in FIG. 25, heat generation may be concentrated at a portion where the first image IM1 is emitted (a first heating portion HS1) and a portion where the second image IM2 is emitted (a second heating portion HS2).

For example, a portion where the heating portions HS1, HS2 are gathered may be the first section PA1, a part spaced and/or apart (e.g., spaced apart or separated) from the first section PA1 may be the second section PA2, and a part between the first section PA1 and the second section PA2 may be the third section PA3, as described in more detail above with respect to FIGS. 6 and 7.

The display device DD and the electronic device EA including the display device DD may have a relatively small power consumption. For example, the power consumption of the display device DD may be only about 0.1 to about 0.2 W/cm². Sufficient heat supply may be desired or required to start a circulation of the working fluid WF. If the working fluid WF of the heat-dissipating device PHP does not circulate, a heat transfer efficiency may decrease. As a non-operation time of the heat- dissipating device PHP becomes longer, a maximum temperature of the display device DD may increase.

The heat-dissipating device PHP according to one or more embodiments of the present disclosure may include the capillary-force controller CFC in the third section PA3. Accordingly, the heat-dissipating device PHP according to one or more embodiments of the present disclosure may improve heat dissipation performance without changing the flow path, working fluid, and dry-out heat capacity (“max Q”).

When changing the flow, fluid properties (viscosity, latent heat, specific heat, thermal conductivity, surface tension, reactivity, vapor pressure, vapor and liquid density, molar mass, and/or the like) must be considered. When changing the working fluid, it may be difficult to find a fluid that changes only one desired or suitable property. When changing the number of turns, dry-out heat (the “max Q”) may increase, but a start-up heat (Q) may decrease, without substantially expanding the effective operating heat range.

However, because the heat-dissipating device PHP according to one or more embodiments of the present disclosure may include the capillary-force controller CFC, the capillary-force controller CFC may lower (quickly lower) the maximum temperature of the display device DD with an initial start-up even with low heat input.

In one or more embodiments, the heat-dissipating device PHP according to one or more embodiments of the present disclosure may control a direction of heat transfer by controlling a degree of cooling at a specific location. For example, the working fluid evaporated in the evaporation section may flow to the condensation section, and the working fluid condensed in the condensation section may flow to the evaporation section, thereby rapidly lowering the maximum temperature of the display device DD. In one or more embodiments, it is also possible to concentrate cooling on a specific location.

In one or more embodiments, the heat-dissipating device PHP according to one or more embodiments of the present disclosure may be designed in one or more suitable ways depending on the location of the heat source, heat capacity, and/or the like. For example, if (e.g., when) heat generation is greatest in a central portion of a monitor, the heat-dissipating device PHP may be positioned to disperse heat from the central portion of the monitor to an edge portion.

In one or more embodiments, the heat-dissipating device PHP according to one or more embodiments of the present disclosure may be customized in consideration of a usage environment. For example, it may be applied to one or more suitable fields such as batteries in addition to display devices DD.

In one or more embodiments, the heat-dissipating device PHP according to one or more embodiments of the present disclosure may be applicable to a vertically driven monitor. In the case of heat-dissipating devices, a length of a vibrating heat pipe may be short, so it cannot be applied to a large-area monitor, and if (e.g., when) installed vertically, the working fluid WF may accumulate at the bottom due to gravity, resulting in a lack of circulation and ineffective heat dissipation. The heat-dissipating device PHP according to one or more embodiments of the disclosure may artificially induce the circulation flow by increasing/decreasing the capillary-force.

In one or more embodiments, the heat-dissipating device PHP according to one or more embodiments of the disclosure may prevent or reduce dry-out by including the energy-change section ECS.

The heat-dissipating device according to one or more embodiments may be applied to a manufacturing process of one or more suitable display devices included in a computer, a notebook, a cell phone, a smart phone, a PMP, a PDA, or a MP3 player.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ± 30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The heat-dissipating device, display device, electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A heat-dissipating device comprising:
a capillary in which a working fluid is to travel, the capillary comprising:
a first section configured to absorb heat generated by a heat source,
a second section spaced from the first section and configured to dissipate the absorbed heat, and
a third section connecting the first section and the second section; and
a capillary-force controller in the third section and configured to increase or decrease capillary-force such that the working fluid absorbing the heat in the first section moves to the second section and the working fluid releasing the heat in the second section moves to the first section.

2. The heat-dissipating device of claim 1, wherein,
the third section comprises a 3-1 subsection to guide the working fluid from the first section to the second section and a 3-2 subsection to guide the working fluid from the second section to the first section, and
the capillary-force controller comprises a surface-treatment part having a surface energy greater in the 3-1 subsection than in the 3-2 subsection.

3. The heat-dissipating device of claim 2, wherein,
the working fluid alternately forms a vapor phase and a liquid phase, and
a contact angle defined by the liquid phase working fluid and the vapor phase working fluid at an inner surface of the surface-treatment part increases along a flow direction in the 3-1 subsection and decreases along the flow direction in the 3-2 subsection.

4. The heat-dissipating device of claim 1, wherein,
the third section comprises a 3-1 subsection to guide the working fluid from the first section to the second section and a 3-2 subsection to guide the working fluid from the second section to the first section, and
the capillary-force controller comprises a diameter-varying part configured such that an inner diameter of the 3-1 subsection increases along a flow direction of the working fluid and an inner diameter of the 3-2 subsection decreases along the flow direction of the working fluid.

5. The heat-dissipating device of claim 1, wherein,
the third section comprises a 3-1 subsection to guide the working fluid from the first section to the second section and a 3-2 subsection to guide the working fluid from the second section to the first section, and
the capillary-force controller comprises a surface area modifier such that a surface area of an inner wall of the 3-1 subsection is smaller than a surface area of an inner wall of the 3-2 subsection.

6. The heat-dissipating device of claim 5, wherein the surface area modifier comprises a protrusion protruding from an inner surface of the 3-2 subsection.

7. The heat-dissipating device of claim 5, wherein the surface area modifier comprises a mesh inside the 3-2 subsection.

8. The heat-dissipating device of claim 5, wherein the surface area modifier comprises linear structures inside the 3-2 subsection.

9. The heat-dissipating device of claim 5, wherein the surface area modifier comprises a porous material inside the 3-2 subsection.

10. An electronic device comprising:
a display device; and
a heat-dissipating device to cool the display device, the heat-dissipating device comprising:
a capillary in which a working fluid is to travel, the capillary comprising:
a first section configured to absorb heat generated by a heat source,
a second section spaced from the first section and configured to dissipate the absorbed heat, and
a third section connecting the first section and the second section; and
a capillary-force controller in the third section and configured to increase or decrease capillary-force such that the working fluid absorbing the heat in the first section moves to the second section and the working fluid releasing the heat in the second section moves to the first section.

11. The electronic device of claim 10, wherein,
the third section comprises a 3-1 subsection to guide the working fluid from the first section to the second section and a 3-2 to guide the working fluid from the second section to the first section, and
the capillary-force controller comprises a surface-treatment part having a surface energy greater in the 3-1 subsection than in the 3-2 subsection.

12. The electronic device of claim 11, wherein,
the working fluid alternately forms a vapor phase and a liquid phase, and
a contact angle defined by the liquid phase working fluid and the vapor phase working fluid at an inner surface of the surface-treatment part increases along a flow direction in the 3-1 subsection and decreases along the flow direction in the 3-2 subsection.

13. The electronic device of claim 10, wherein,
the third section comprises a 3-1 subsection to guide the working fluid from the first section to the second section and a 3-2 subsection to guide the working fluid from the second section to the first section, and
the capillary-force controller comprises a diameter-varying part configured such that an inner diameter of the 3-1 subsection increases along a flow direction of the working fluid and an inner diameter of the 3-2 subsection decreases along the flow direction of the working fluid.

14. The electronic device of claim 10, wherein,
the third section comprises a 3-1 subsection to guide the working fluid from the first section to the second section and a 3-2 subsection to guide the working fluid from the second section to the first section, and
the capillary-force controller comprises a surface area modifier such that a surface area of an inner wall of the 3-1 subsection is smaller than a surface area of an inner wall of the 3-2 subsection.

15. The electronic device of claim 14, wherein the surface area modifier comprises:
at least one selected from a group consisting of a protrusion protruding from an inner surface of the 3-2 subsection, a mesh inside the 3-2 subsection, linear structures inside the 3-2 subsection, and a porous material inside the 3-2 subsection.

16. The electronic device of claim 10, further comprising:
a surface-energy-change section on a portion of an inner surface of a flow path, the surface-energy-change section comprising a first zone and a second zone that alternate with each other, the first zone having a first surface energy, and the second zone having a second surface energy different from the first surface energy.

17. The electronic device of claim 16, wherein,
an inner surface of the first zone is hydrophilic, and
an inner surface of the second zone is hydrophobic.

18. A heat-dissipating method of an electronic device comprising:
forming, on a portion of an inner surface of a flow path, a surface-energy-change section comprising a first zone and a second zone that alternate with each other, the first zone having a first surface energy, and the second zone having a second surface energy lower than the first surface energy;
charging the flow path with a working fluid; and
dissipating heat from a heat source while the working fluid travels through the flow path.

19. The heat-dissipating method of claim 18,
wherein the working fluid alternately forms a vapor phase and a liquid phase, and
wherein the step of dissipating the heat from the heat source while the working fluid travels through the flow path comprises:
interrupting the flow of the liquid phase working fluid at an interface between the first zone and the second zone;
forming a liquid column by surface tension at the interface; and
reducing a size of the vapor phase working fluid by the liquid column.

20. The heat-dissipating method of claim 18, wherein the heat source comprises at least one selected from a group consisting of: a display device comprising multiple pixels and an electronic device comprising the display device and an outer case accommodating the display device.
